(19) United States
(12) Patent Application Publication
(10) Pub. No.: US 2026/0237570 A1
(43) Pub. Date: Aug. 13, 2026

(54) MEMS COMPONENT AND METHOD FOR PRODUCING A MEMS COMPONENT

(71) Applicant: Robert Bosch GmbH, Stuttgart (DE)

(72) Inventors: Carina Morstein, Filderstadt (DE); Jochen Reinmuth, Reutlingen (DE)

(21) Appl. No.: 19/463,234

(22) Filed: Jan. 29, 2026

(30) Foreign Application Priority Data
Feb. 10, 2025 (DE) 10 2025 104 702.2

(51) Int. Cl. H01H 1/00; H01H 49/00; H01H 50/00; H01H 50/54

(52) U.S. Cl. CPC H01H 1/0036; H01H 49/00; H01H 50/005; H01H 50/548; H01H 2001/0057

(57) ABSTRACT

A MEMS component, in particular a MEMS relay. The MEMS component includes a first component element and a second component element that is movable relative to the first component element in a contacting direction, wherein a first contact element is formed on the first component element and a second contact element is formed on the second component element, wherein the first contact element protrudes from a first element surface of the first component element and/or the second contact element protrudes from a second element surface of the second component element, wherein a regeneration layer is formed on the first element surface and/or on the second element surface, and wherein the regeneration layer is designed to be atomized during sparking caused by contacting of the first and second contact elements. A method for producing a MEMS component is also described.

### FIELD

The present disclosure relates to a MEMS component and a method for producing a MEMS component.

### BACKGROUND INFORMATION

Certain MEMS components, in particular MEMS relays, are described in the related art.

### SUMMARY

It is an object of the present disclosure to provide an improved MEMS component and an improved method for producing a MEMS component.

The object may be achieved by a MEMS component and a method of having certain features of the present disclosure. Advantageous embodiments are disclosed herein.

According to one aspect, a MEMS component, in particular a MEMS relay, is provided. According to an example embodiment, the MEMS component has a first component element and a second component element that is movable in a contacting direction relative to the first component element, wherein a first contact element is formed on the first component element and a second contact element is formed on the second component element, wherein the first contact element protrudes from a first element surface of the first component element and/or the second contact element protrudes from a second element surface of the second component element, wherein a regeneration layer is formed on the first element surface and/or on the second element surface, and wherein the regeneration layer is designed to be atomized by sparking caused by contacting of the first and second contact elements.

This can achieve a technical advantage that an improved MEMS component, in particular an improved MEMS relay, can be provided. The MEMS component comprises two component elements that are movable relative to each other. At least one contact element is formed on each component element. The movement of the component elements relative to each other can cause contacting of the contact elements and thus the MEMS relay to be closed. A regeneration layer is formed on at least one element surface of at least one component element in the immediate vicinity of the relevant contact element. The regeneration layer is designed to be atomized during sparking caused by contacting of the contact elements.

By atomization of the regeneration layer, the atomized regeneration layer is deposited on the relevant contact element. Depositing the atomized regeneration layer on the contact element regenerates the contact element and can delay or prevent wear of the relevant contact element caused by the contacting during the switching operations of the MEMS relay. This can increase the service life of the MEMS relay.

The atomized regeneration layer deposited onto the contact elements is stimulated to diffuse into the material of the contact elements during subsequent switching operations of the MEMS relay and the associated contacting of the contact elements and the heat generated as a result. This regenerates the relevant contact element and reduces or prevents wear.

According to one example embodiment, the regeneration layer is made of a material that has a lower degree of hardness than a material of the first and/or second contact elements.

This can achieve a technical advantage that improved atomization of the regeneration layer is caused by sparking caused by the contacting of the contact elements. By making the regeneration layer from a softer material than the contact elements, the regeneration layer is atomized more intensely than the contact elements during sparking. This can result in the wear of the contact elements being reduced or avoided by the deposition of the atomized regeneration layer on the contact elements.

According to one example embodiment, the first contact element protrudes from the first element surface and/or the second contact element protrudes from the second element surface and each has a contacting surface spaced apart from the element surface, wherein the regeneration layer has a layer thickness that is less than or equal to a distance between the contacting surface of the relevant contact element and the element surface of the relevant component element.

This can achieve a technical advantage that, by making the layer thickness of the regeneration layer smaller than the distance between the contacting surface of the contact element and the element surface, a distance is created between the contacting surface of the contact element and a surface of the regeneration layer. The distance ensures that, during the contacting of the contact elements as the MEMS relay closes, the regeneration layer does not contact any other element of the other component.

This achieves undisturbed contacting of the contact elements and thus undisturbed switching of the MEMS relay. By accordingly selecting the distance between the contacting surface of the contact element and the surface of the regeneration layer, optimal atomization of the regeneration layer can be achieved during sparking caused by contacting of the contact elements, and thus an optimal deposition of the atomized regeneration layer on the contact surface of the relevant contact element can be achieved.

According to one example embodiment, the regeneration layer at least partially covers the contacting surface and/or a side surface of the contact element.

This can achieve a technical advantage that the formation of the regeneration layer on the contacting surface and/or on a side surface of the contact element results in improved atomization of the regeneration layer when the contact elements make contact and a correspondingly improved deposition of the atomized regeneration layer on the contact element.

Furthermore, by performing the contacting of the contact elements and generating heat by means of the contacting, the regeneration layer already formed on the contact surface diffusing into the material of the contact elements can also be achieved. This can further improve the regeneration of the contact elements.

According to one example embodiment, a plurality of pin-shaped first contact elements is formed on the first component element, wherein a planar second contact element is formed on the second component element, and wherein the planar second contact element is designed to contact the plurality of first contact elements.

This can achieve a technical advantage of improved contacting of the contact elements and thus improved switching behavior of the MEMS relay.

According to one example embodiment, the first and/or second contact elements are made of a material from the following list: tungsten, tantalum, molybdenum, ruthenium, and wherein the regeneration layer is made of a material from the following list: gold, silver, copper, and/or wherein the first contact element and/or the second contact element have an extent along a surface normal of the first and/or second element surface of up to 5 μm and perpendicular to the surface normal of 32 μm, and/or wherein the layer thickness of the regeneration layer is between 1 nm and 100 nm, and/or wherein a distance between the contacting surface of the contact element and the surface of the regeneration layer is 10 nm to 3 μm.

This can achieve a technical advantage that, by selecting the material for the contact elements, a particularly hard contact element can be provided, resulting in improved contacting and reduced wear of the contact elements.

By appropriately selecting the material for the regeneration layer, a regeneration layer that is as soft as possible can be provided, which can be atomized to a high degree by the sparking from contacting of the contact elements. This can result in improved deposition of the regeneration layer onto the contact elements and the associated regeneration of the contact elements.

By appropriately sizing the contact elements and/or the regeneration layer, optimal contacting of the contact elements and/or deposition of the atomized regeneration layer onto the contact elements can be achieved.

According to an aspect of the present disclosure, a method is provided for producing a MEMS component according to one of the above-described embodiments. According to an example embodiment, the method comprises:

providing a component element which has at least one contact element, wherein the component element comprises a substrate and an insulating layer formed on the substrate, and wherein the at least one contact element protrudes from an element surface defined by a surface of the insulating layer;
depositing a regeneration layer onto the insulating layer and at least partially covering the at least one contact element and/or the surface of the insulating layer with the regeneration layer; removing the regeneration layer from a contacting surface of the contact element; and/or
removing the regeneration layer from the insulating layer and creating a distance between the contacting surface of the contact element and a surface of the regeneration layer.

This can achieve a technical advantage that an improved method for producing a MEMS component can be provided. For this purpose, a component element is first provided which has a substrate, an insulating layer formed on the substrate and at least one contact element formed on the insulating layer. Subsequently, a regeneration layer is deposited onto the surface of the insulating layer such that the regeneration layer at least partially covers the surface of the insulating layer and the relevant contact elements. Subsequently, the regeneration layer is removed at least from the contacting surface of the contact element. Finally, the layer thickness of the regeneration layer is reduced such that the distance is established between the surface of the regeneration layer and the contacting surface of the contact element. This allows the simplest possible production of the MEMS component.

According to one example embodiment, providing the component element comprises:

providing the substrate which has the insulating layer formed on the substrate;
etching at least one recess into the insulating layer;
depositing a contact layer onto the insulating layer formed by the recess and at least partially filling the recess with the contact layer;
removing the contact layer from the surface of the insulating layer and creating a distance between the contacting surface of the contact element and the surface of the insulating layer.

This can achieve a technical advantage that an individual design of the MEMS component is made possible. For this purpose, at least one recess is etched into the insulating layer to create the at least one contact element of the component element for providing the component element. Subsequently, the contact layer made from the material of the contact element is applied to the surface of the insulating layer, such that the at least one recess is at least partially filled by the contact layer. Subsequently, the contact layer is removed from the surface of the insulating layer. This allows for a technically simple production method for the contact elements.

According to one example embodiment, the method further comprises:

depositing a further regeneration layer onto the regeneration layer and at least partially covering the contacting surface of the contact element by means of the regeneration layer; and/or structuring the regeneration layer by performing a structuring process.

This can achieve a technical advantage that, by deactivating the further regeneration layer, a coating of the contact element with the regeneration layer can be effected onto the contacting surface of the contact element. This allows for improved diffusion of the regeneration layer into the contact element during switching operations of the MEMS relay that are performed.

According to one example embodiment, the insulating layer comprises a first partial layer, a second partial layer and an electrode layer formed between the partial layers, wherein the depression recess is formed in one of the partial layers up to the electrode layer.

This can achieve a technical advantage of a simple design of the MEMS relay with a switchable electrode integrated into the insulating layer for switching the switching operations of the MEMS relay.

Embodiments of the present disclosure are described with reference to the figures.

### BRIEF DESCRIPTION OF THE DRAWINGS

FIG. 1 is a schematic representation of a MEMS component according to one embodiment;

FIG. 2 is a further schematic representation of a MEMS component according to one embodiment;

FIG. 3 is a further schematic representation of a MEMS component according to one embodiment;

FIG. 4 is a further schematic representation of a MEMS component according to one embodiment; and

FIG. 5-12 are graphical representations of method steps of a method for producing a MEMS component according to one embodiment.

### DETAILED DESCRIPTION OF EXAMPLE EMBODIMENTS

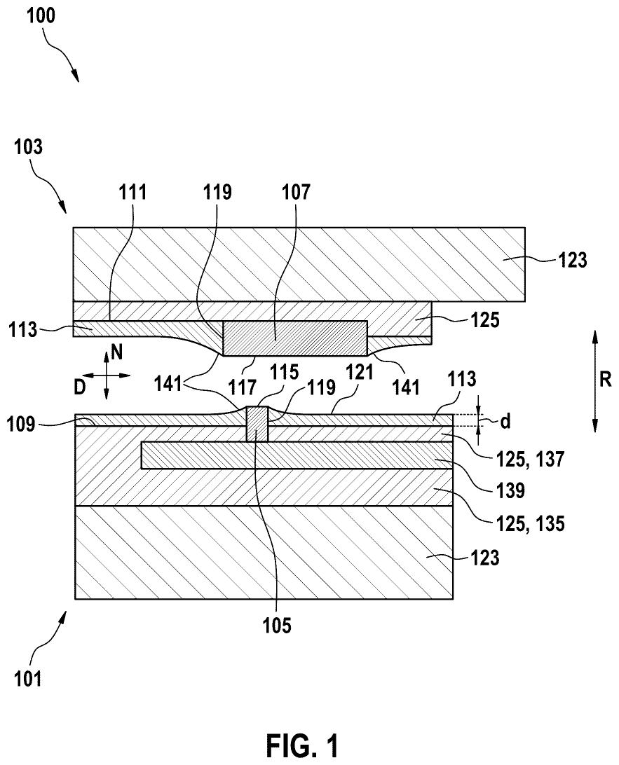

FIG. 1 is a schematic representation of a MEMS component 100 according to one embodiment.

According to the disclosure, the MEMS component 100 comprises a first component element 101 and a second component element 103. The first and second component elements 101, 103 are movable relative to each other in a contacting direction R.

On a first element surface 109, the first component element 101 comprises a first contact element 105. On a second element surface 111 that faces one of the first element surfaces 109, the second component element 103 comprises a second contact element 107 formed correspondingly opposite the first contact element 105.

By performing a switching operation, one of the contact elements 105, 107 can be supplied with a corresponding electrical voltage. The electric field generated thereby attracts the other contact element 105, 107 and contacting the two contact elements 105, 107 can cause the MEMS component 100, in particular the MEMS relay, to close.

According to the disclosure, a regeneration layer 113 is formed on at least one of the element surfaces 109, 111 of the first and second component elements 101, 103. The regeneration layer 113 is formed directly adjacent to the relevant contact element 105, 107. The regeneration layer 113 is designed to be atomized by sparking caused by contacting the two contact elements 105, 107 with each other.

The atomized regeneration layer is subsequently deposited on the relevant contact element 105, 107 and diffuses into the material of the relevant contact element 105, 107. This effects the regeneration of the relevant contact element 105, 107 and reduces the wear of the contact element 105, 107 and extends its service life.

According to one embodiment, the regeneration layer 113 is made of a material that has a lower degree of hardness than the material of the relevant contact element 105, 107.

According to one embodiment, the contact elements 105, 107 are made of a material from the following list: tungsten, tantalum, molybdenum, ruthenium. The regeneration layer 113 can be made from a material from the following list: gold, silver, copper.

In the embodiment shown, a regeneration layer 113 is formed on each of the two element surfaces 109, 111 of the first and second component elements 101, 103. The regeneration layer 113 is formed on both sides, with respect to an extension direction D that is perpendicular to a normal direction L, for the relevant contact element 105, 107.

In the embodiment shown, the regeneration layer 113 is thus formed laterally with respect to the relevant contact elements 105, 107. The contact elements 105, 107 have contacting surfaces 115, 117 aligned parallel to the element surfaces 109, 111 and facing each other. The two contact elements 105, 107 are contacted via the contacting surfaces 115, 117 when the MEMS relay is switched.

In the embodiment shown, the contacting surfaces 115, 117 are each uncovered by the regeneration layer 113.

By contrast, the side surfaces 119 of the respective contact elements 105, 107 arranged perpendicularly to the contacting surfaces 115, 117 are covered by the regeneration layer 113.

In the embodiment shown, the first component element comprises a substrate 123. An insulating layer 125 is formed on the substrate 123. In the embodiment shown, the insulating layer 125 comprises a first partial layer 135 and a second partial layer 137. An electrically conductive electrode layer 139 is formed between the partial layers 135, 137. In the embodiment shown, the contact element 105 is integrated into the second partial layer 137 and contacts the electrode layer 139, thereby causing an electrical connection of the contact element 105 to the electrode layer 139.

By controlling the electrode layer 139, the first contact element 105 can thus be supplied with a corresponding electrical voltage in order to attract the second contact element 107 of the second component element 103 and to effect a corresponding switching process by contacting the two contact elements 105, 107.

In the embodiment shown, the regeneration layers 113 also have chamfers 141. The chamfers 141 are arranged directly to the side surfaces 119 of the respective contact elements 105, 107 and cause the layer thickness d of the regeneration layer to decrease with respect to the normal direction N as the distance with respect to the extension direction D increases.

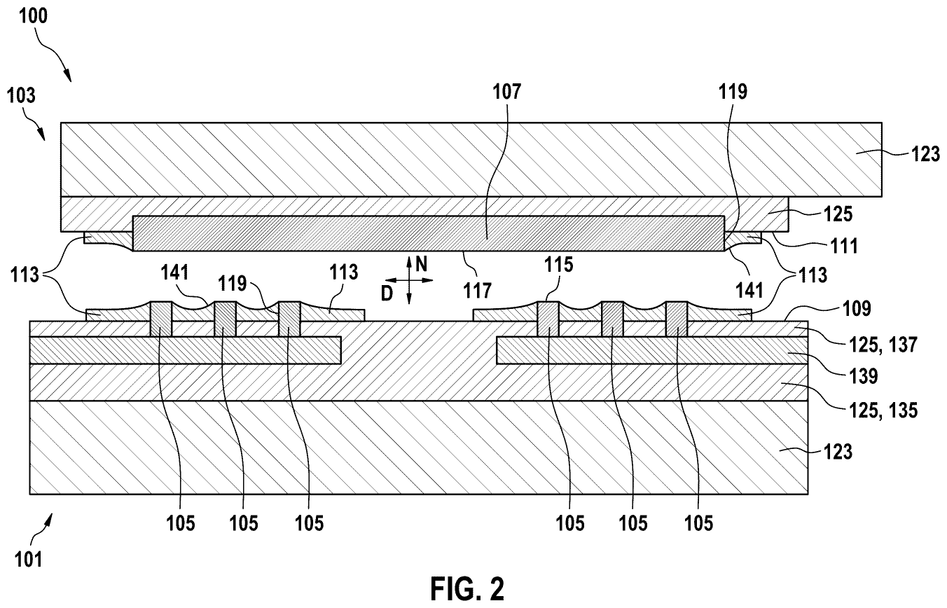

FIG. 2 is a further schematic representation of a MEMS component 100 according to one embodiment.

The embodiment shown is based on the embodiment in FIG. 1 and comprises all the features described there. In the embodiment shown, the second contact element 107 of the second component element 104 is formed in a planar shape and extends in the extension direction D.

The first component element 101, on the other hand, comprises a plurality of first contact elements 105. The first contact elements 105 are pin-shaped and arranged spaced apart from each other along the extension direction D. The individual contact elements 105 are each electrically contacted with the electrode layer 139, thereby allowing the switching capacity of the MEMS relay.

The planar second contact element 107 of the second component element 103 is designed to simultaneously contact the plurality of first contact elements 105 of the first component element 101.

In the embodiment shown, all contact elements 105, 107 are provided with the regeneration layer 113, which is formed adjacent to the contact elements 105, 107 with respect to the extension direction D. The side surfaces 119 of the contact elements 105, 107 are each at least partially covered by the regeneration layer 113.

In the embodiment shown, the contacting surfaces 115, 117 of the contact elements 105, 107, by contrast, are uncovered by the regeneration layer 113.

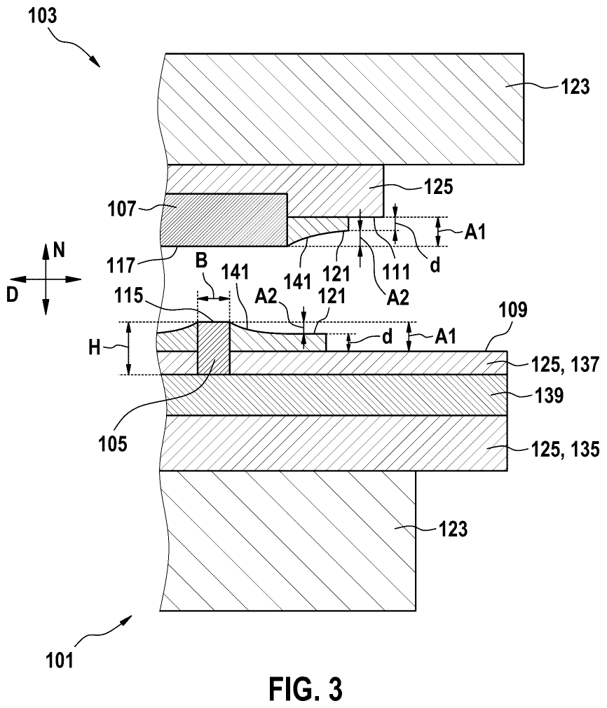

FIG. 3 is a further schematic representation of a MEMS component 100 according to one embodiment.

The embodiment of FIG. 3 is based on the embodiment of FIG. 1 or FIG. 2 and comprises all the features described there.

FIG. 3 shows only a portion of the MEMS component 100 in order to improve the readability of FIG. 3.

In the embodiment shown, the contact elements 105, 107 are designed such that a distance Al between the relevant contacting surface 115, 117 and the relevant element surface 109, 111 is greater than a layer thickness d of the regeneration layer 113. This results in a distance A2 between the relevant contacting layer 115, 117 of the relevant contact element 105, 107 and a surface 121 of the regeneration layer 113.

In the embodiment shown, the chamfers 141 are again depicted. The chamfers 141 again ensure that the regeneration layer 113 completely covers the side surface 119 of the relevant contact element 105, 107 and that the layer thickness d decreases with increasing distance to the contact element 105, 107 in relation to the extension direction D. The layer thickness d of the regeneration layer 113 refers here to a region outside the chamfer 141 in which the relevant regeneration layer 113 has a largely uniform layer thickness d.

According to one embodiment, the contact elements 105, 107 have a height H of up to 5 u defined with respect to the normal direction N.

According to one embodiment, the contact elements 105, 107 have a width B with respect to the extension direction D of up to 32 μ.

According to one embodiment, the regeneration layer 113 has a layer thickness between 1 nm and 1000 nm.

According to one embodiment, the distance A2 between the contacting surface 115, 117 of the relevant contact element 105, 107 and the surface 121 of the relevant regeneration layer 113 is 10 nm to 3 μ.

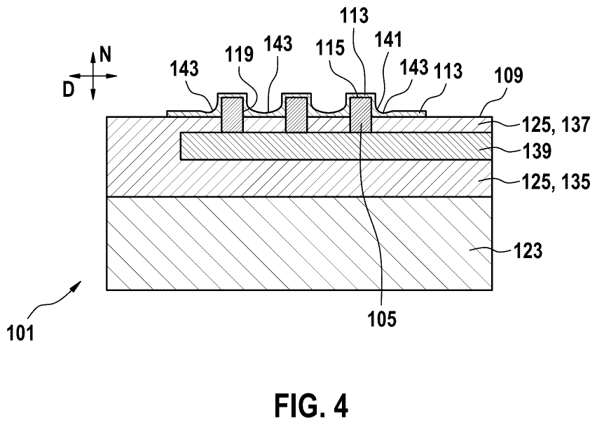

FIG. 4 is a further schematic representation of a MEMS component 100 according to one embodiment.

The embodiment shown is based on the embodiment in FIG. 2. FIG. 4 shows only the first component element 101 in order to improve the resolvability of the figure.

In the embodiment shown, the regeneration layer 113 is also formed on the contacting surfaces 115 of the contact elements 105 shown.

Furthermore, the contacting surface 115 has depressions 143 immediately adjacent to the side surfaces 119 of the contact elements 105. The depressions 143 are almost circular and adjoin the chamfers 141 directly. The layer thickness d is reduced by the depressions 143 in the immediate vicinity of the contact element 105.

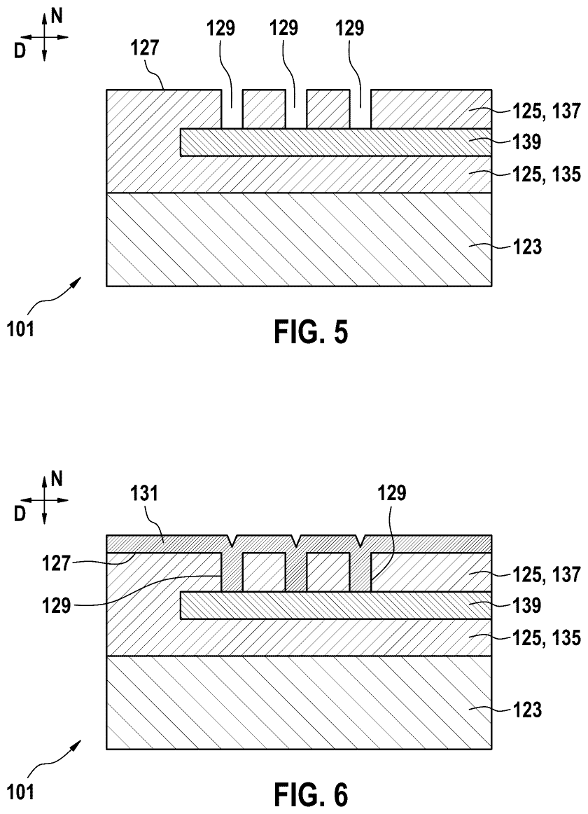

FIG. 5 to 12 show graphical representations of method steps of a method for producing a MEMS component 100 according to one embodiment.

According to the present disclosure, in order to produce a MEMS component 100 according to the embodiments described above, a component element 101, 103 is first provided which has at least one contact element 105, 107 in a first method step, wherein the component element 101, 103 comprises a substrate 123 and an insulating layer 125 formed on the substrate 123, wherein the contact element 105, 107 protrudes from an element surface 109, 111 defined by a surface 127 of the insulating layer 125.

This is achieved through the method steps shown in FIG. 5 to 8.

In the embodiment shown, to provide the component element 105, 107 in the method steps shown in FIG. 5, the substrate 123 is first provided which has the insulating layer 125 formed thereon.

Subsequently, at least one recess 129 is etched into the surface 127 of the insulating layer 125.

In the embodiment shown, the insulating layer 125 again comprises the first partial layer 135 and the second partial layer 137. The electrode layer 139 is formed between the two partial layers 135, 137.

In the embodiment shown, at least one recess 129 is incorporated into the second partial layer 137 as far as the electrically conductive electrode layer 139.

In the embodiment shown in FIG. 6, a contact layer 131 is subsequently deposited onto the surface 127 of the insulating layer 125. The contact layer 131 is applied to the insulating layer 125 in such a way that the at least one recess 129 is at least partially filled by the contact layer 131.

The contact layer 131 can, as mentioned above, comprise tungsten, molybdenum, tantalum or ruthenium. The deactivation of contact layer 131 can be achieved, for example, via a MOCVD method.

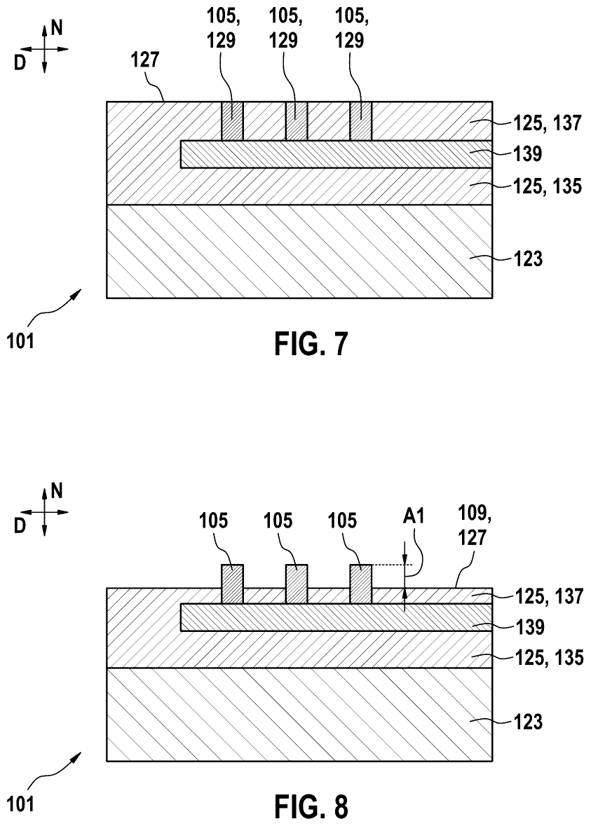

In the method step shown in FIG. 7, the contact layer 131 is removed from the insulating layer 125. The surface 127 of the insulating layer 125 is thereby completely freed from the contact layer 131, so that the contact layer 131 remains exclusively in the at least one recess 129. The removal of the contact layer can be achieved, for example, by a CMP method.

In the method step shown in FIG. 8, the insulating layer 125 is subsequently at least partially removed. In the embodiment of the second partial layer 137 that is shown, the layer thickness of the insulating layer 125 is reduced in the immediate vicinity of the at least one contact element 105 such that the distance A1 between the contacting surface 115 of the contact element 105 and the surface 127 of the insulating layer 125 is created. The surface 127 of the insulating layer 125 forms the element surface 109 of the shown component element 101. The insulating layer 125 can be removed by a selective etching method, e.g., a CF4-containing plasma etching method or an HF-containing wet etching method.

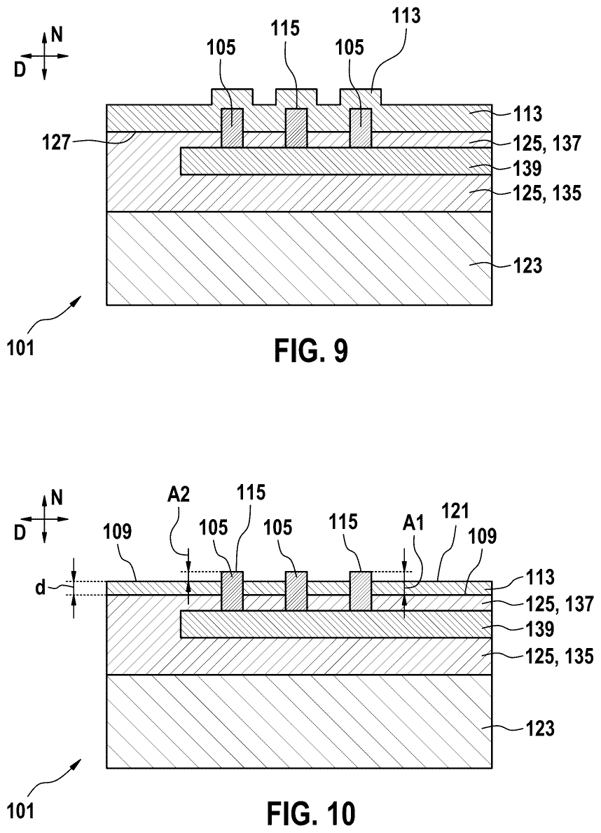

In the method step shown in FIG. 9, the regeneration layer 113 is subsequently deposited onto the surface 127 of the insulating layer 125. The regeneration layer 113 is deposited in such a way that the regeneration layer 113 at least partially covers the surface 127 of the insulating layer 125 and/or the contact element 105.

In the execution step shown in FIG. 10, the regeneration layer 113 is partially removed again. The regeneration layer 113 is removed in particular from the contacting surface 115 of the contact element 105 that is shown. In the embodiment shown, the layer thickness d of the regeneration layer 113 is further reduced in such a way that the distance A2 between the contacting surface 115 of the contact element 105 and the surface 121 of the regeneration layer 113 is created.

In the embodiment shown, the regeneration layer has an almost constant layer thickness d. Chamfers 141, as shown in the embodiments above, do not occur. The regeneration layer 113 is nevertheless formed up to the point of contacting of the side surfaces 119 of the at least one contact element 105 and the relevant contact element 105.

The removal of the regeneration layer 113 can be achieved, for example, by a selective etching method.

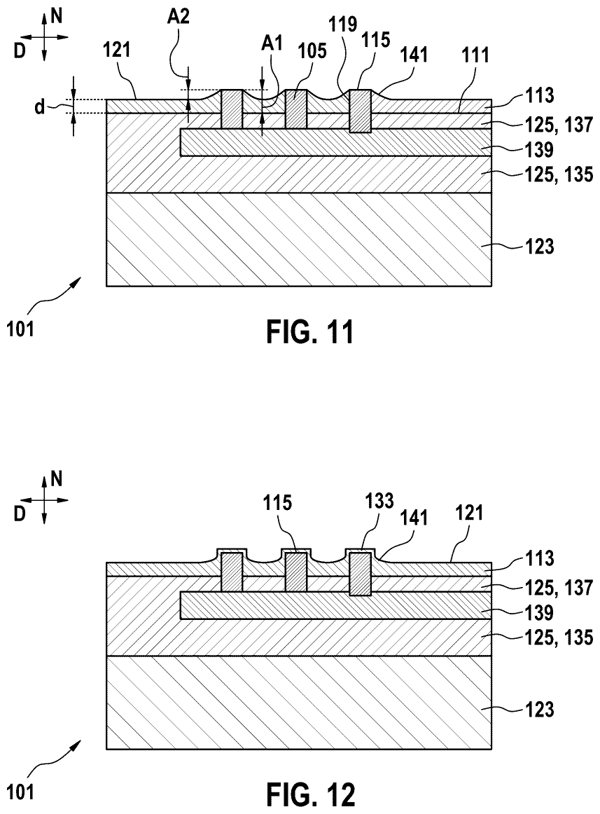

In the embodiment shown in FIG. 11, the removal of the regeneration layer 113 from the at least one contact element 105 has been effected by an ion beam method at an oblique ion incidence. The oblique ion incidence removes the regeneration layer 113 from the contacting surface 115 of the relevant contact element 105.

The chamfering 141 of the regeneration layer 113 is caused by the oblique ion incidence and the resulting shadowing with respect to the direction of the ion beam behind the contact element 105. Due to the chamfer 141 caused by the shadowing during the etching method via the contact element 105, the regeneration layer 113 has, directly at the contact element 105, the same height as the contact element 105 and thus completely covers the relevant side surface 119.

In the optional method step shown in FIG. 12, an additional regeneration layer 133 can be formed by another deposition on the contacting surface 115 of the at least one contact element 105.

FIG. 5 to 12 show the production of a first component element 101 with an electrode layer 139.

However, the method steps shown can also be applied to the production of a second component element 103 of the MEMS component 100.

According to one embodiment, a coating of the contacting surfaces 115, 117 of the contact element 105, 107 can also be produced by performing switching operations of the MEMS component 100 at the factory in order to cause atomization of the regeneration layer 113 and deposition of the regeneration layer onto the relevant contacting surfaces 115, 117 of the contact elements 105, 107.

1-10. (canceled)

11. A MEMS component, comprising:
a first component element; and
a second component element that is movable relative to the first component element in a contacting direction;
wherein a first contact element is formed on the first component element, and a second contact element is formed on the second component element,
wherein the first contact element protrudes from a first element surface of the first component element and/or the second contact element protrudes from a second element surface of the second component element,
wherein a regeneration layer is formed on the first element surface and/or on the second element surface, and
wherein the regeneration layer is configured to be atomized during sparking caused by contacting of the first contact element and the second contact element.

12. The MEMS component according to claim 11, wherein the MEMS component is a MEMS relay.

13. The MEMS component according to claim 11, wherein the regeneration layer is made of a material which has a lower degree of hardness than a material of the first contact element and/or the second contact element.

14. The MEMS component according to claim 11, wherein the first contact element protrudes from the first element surface and/or the second contact element protrudes from the second element surface, and each has a contacting surface spaced apart from the first and/or second element surface, and wherein the regeneration layer has a layer thickness that is less than or equal to a distance between the contacting surface of the first and/or second contact element and the first and/or second element surface of the first and/or second component element.

15. The MEMS component according to claim 13, wherein the regeneration layer at least partially covers the contacting surface and/or a side surface of the first and/or second contact element.

16. The MEMS component according to claim 11, wherein a plurality of pin-shaped first contact elements is formed on the first component element, wherein a planar second contact element is formed on the second component element, and wherein the planar second contact element is configured to contact the plurality of first contact elements.

17. The MEMS component according to claim 11, wherein at least one of the following:
the first and/or second contact elements are made of a material from the following list: tungsten, tantalum, molybdenum, ruthenium,
the regeneration layer is made of a material from the following list: gold, silver and copper,
the first contact element and/or the second contact element have an extent along a surface normal of the first and/or second element surface of up to 5 μm and an extent perpendicular to the surface normal of 32 μm,
a layer thickness of the regeneration layer is between 1 nm and 100 nm,
a distance between the contacting surface of the first and/or second contact element and a surface of the regeneration layer is 10 nm to 3 μm.

18. A method for producing a MEMS component, comprising the following steps:
providing a component element which has at least one contact element, wherein the component element includes a substrate and an insulating layer formed on the substrate, and wherein the at least one contact element protrudes from an element surface defined by a surface of the insulating layer;
depositing a regeneration layer onto the insulating layer and at least partially covering the at least one contact element and/or the surface of the insulating layer by the regeneration layer; and at least one of:
removing the regeneration layer from a contacting surface of the contact element, and/or
removing the regeneration layer from the insulating layer and creating a distance between the contacting surface of the at least one contact element and a surface of the regeneration layer.

19. The method according to claim 18, wherein providing the component element includes:
providing the substrate which has the insulating layer formed on the substrate;
etching a recess into the insulating layer;
depositing a contact layer onto the insulating layer formed with the at least one recess and at least partially filling the recess with the contact layer;
removing the contact layer from the surface of the insulating layer and creating a distance between the contacting surface of the contact element and the surface of the insulating layer.

20. The method according to claim 18, further comprising at least one of:
depositing a further regeneration layer onto the regeneration layer and at least partially covering the contacting surface of the contact element with the further regeneration layer; and/or
structuring the regeneration layer by performing a structuring process.

21. The method according to claim 18, wherein the insulating layer includes a first partial layer, a second partial layer, and an electrode layer formed between the partial layers, and wherein the recess is formed in one of the first and second partial layers, up to the electrode layer.
